(19) United States
(12) Patent Application Publication
(10) Pub. No.: US 2025/0197551 A1
(43) Pub. Date: Jun. 19, 2025

(54) RESIN COMPOSITION FOR FORMING PHASE-SEPARATED STRUCTURE, METHOD FOR PRODUCING STRUCTURE HAVING PHASE-SEPARATED STRUCTURE, AND BLOCK COPOLYMER

(71) Applicant: TOKYO OHKA KOGYO CO., LTD., Kawasaki-shi (JP)

(72) Inventors: Ryutaro SUGAWARA, Kawasaki-shi (JP); Shota IINO, Kawasaki-shi (JP); Takehiro SESHIMO, Kawasaki-shi (JP); Takahiro DAZAI, Kawasaki-shi (JP)

(21) Appl. No.: 18/974,245

(22) Filed: Dec. 9, 2024

(30) Foreign Application Priority Data
Dec. 13, 2023 (JP) 2023-210146

(51) Int. Cl. C08F 297/02; G03F 7/00

(52) U.S. Cl. CPC C08F 297/026; G03F 7/0002

(57) ABSTRACT

A resin composition for forming a phase-separated structure, the resin composition including a block copolymer having a first block and a second block, the first block including a polymer having a repeating structure of a constituent unit represented by the following formula (b1), the second block including a random copolymer having a structure in which a constituent unit represented by the following formula (b2a) and a constituent unit represented by the following formula (b2b) are randomly arranged, and a ratio of a volume of the first block being 20% by volume or more and 80% by volume or less

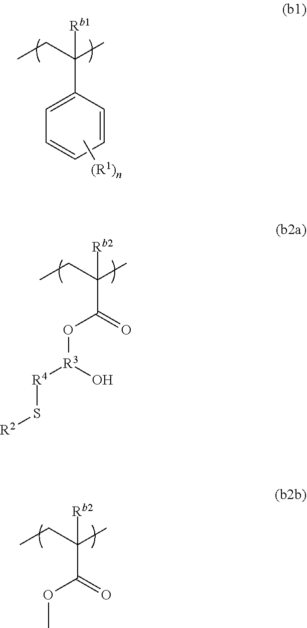

### RELATED APPLICATIONS

This application claims priority to Japanese Patent Application No. 2023-210146, filed Dec. 13, 2023, the entire content of which is incorporated herein by reference.

### BACKGROUND OF THE INVENTION

### Field of the Invention

The present invention relates to a resin composition for forming a phase-separated structure, a method for producing a structure having a phase-separated structure, and a block copolymer.

### Related Art

In recent years, following further miniaturization of a large-scale integrated circuit (LSI), a technique for processing a finer structure has been demanded. For such a demand, a technique has been developed for forming a finer pattern utilizing a phase-separated structure formed by self-organization of a block copolymer in which blocks incompatible with each other are bonded (see, for example, Patent Document 1). In order to utilize the phase-separated structure of the block copolymer, it is essential for a self-organized nanostructure formed by microphase separation to be formed only in a specific region and oriented in a desired direction. In order to control the position and orientation of these nanostructures, processes such as graphoepitaxy for controlling a phase separation pattern by a guide pattern and chemical epitaxy for controlling a phase separation pattern based on a difference in a chemical state of a substrate have been proposed (see, for example, Non-Patent Document 1).

The block copolymer forms a structure having a regular periodic structure by phase separation. The phrase “structural period” means a period of a phase structure observed when a structure having a phase-separated structure is formed and refers to a sum of lengths of phases incompatible with each other. In a case where a phase-separated structure forms a cylindrical structure perpendicular to a surface of a substrate, a structural period (L₀) is a distance between centers (pitch) of two adjacent cylindrical structures.

It has been known that a structural period (L₀) is determined by inherent polymerization properties such as a degree of polymerization N and the Flory-Huggins interaction parameter χ. That is, the larger the product “χ·N” of χ and N, the greater the mutual repulsion between different blocks in the block copolymer becomes. Therefore, in the case of χ·N>10.5 (hereinafter, referred to as “intensity separation limit”), repulsion between different blocks in the block copolymer is large, leading to a stronger tendency to cause phase separation. Accordingly, at the intensity separation limit, the structural period is approximately N^{2/3}·χ^{1/6} and a relationship of the following expression (1) is satisfied. That is, the structural period is proportional to the degree of polymerization N, which correlates with a molecular weight and a molecular weight ratio between different blocks.

$${L}_{0} ∝ a \cdot {N}^{2 / 3} \cdot {χ}^{1 / 6} \qquad ( 1 )$$

wherein L₀ denotes a structural period; a is a parameter indicating a size of a monomer; N denotes a degree of polymerization; and χ is an interaction parameter, and a higher value means higher phase separation performance.

Accordingly, the structural period (L₀) can be controlled by adjusting a composition and a total molecular weight of a block copolymer. It has been known that the periodic structure formed by the block copolymer changes to a cylinder (columnar), a lamellar (plate-like), and a sphere (spherical) depending on a volume ratio of a polymer component or the like, and a period thereof depends on a molecular weight. Therefore, in order to form a structure having a relatively large period (L₀) by utilizing a phase-separated structure formed by self-organization of a block copolymer, a method of increasing a molecular weight of the block copolymer is considered.

In addition, a method using a block copolymer having an interaction parameter (χ) larger than that of a block copolymer having a block of styrene and a block of methyl methacrylate, which is a general-purpose block copolymer, is considered. For example, Non-Patent Document 2 proposes a block copolymer composed of a block of styrene and a block of 2-hydroxy-3-(2,2,2-trifluoroethylsulfanyl) propyl methacrylate.
Patent Document 1: Japanese Unexamined Patent Application, Publication No. 2008-36491
Non-Patent Document 1: Proc. SPIE 7637, Alternative Lithographic Technologies II, 76370G (1 Apr. 2010)
Non-Patent Document 2: Yoshimura et al. Chemically tailored high-χblock copolymers for perpendicular lamellae via thermal annealing. Soft Matter, 2019, 15, 3497-3506.

### SUMMARY OF THE INVENTION

In order to form a fine pattern by utilizing a phase-separated structure formed by self-organization of a block copolymer, it is preferable that the phase-separated structure formed by the block copolymer has a vertical orientation. However, the block copolymer described in Non-Patent Document 2 cannot form a phase-separated structure having a vertical orientation.

The present invention has been made in view of the above circumstances, and an object of the present invention is to provide a resin composition for forming a phase-separated structure capable of forming a phase-separated structure having an excellent vertical orientation, a method for producing a structure having a phase-separated structure using the same, and a block copolymer for use in the resin composition for forming a phase-separated structure.

As a result of extensive studies to solve the above problem, the present invention has been completed based on findings that the above object can be solved if a predetermined block copolymer is used. Specifically, the present invention provides the following aspects.

A first aspect relates to a resin composition for forming a phase-separated structure, the resin composition containing:
a block copolymer having a first block and a second block, the first block being composed of a polymer having a repeating structure of a constituent unit represented by the following formula (b1),
the second block being composed of a random copolymer having a structure in which a constituent unit represented by the following formula (b2a) and a constituent unit represented by the following formula (b2b) are randomly arranged,
a ratio of a volume of the first block to a total of the volume of the first block and a volume of the second block being 20% by volume or more and 80% by volume or less,

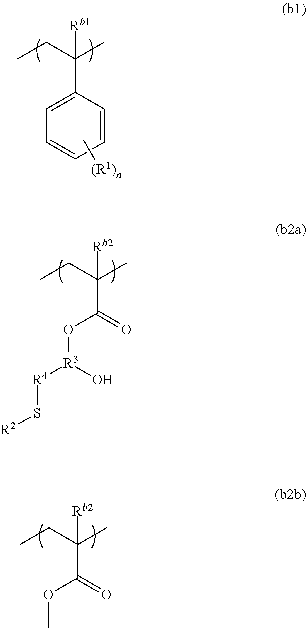

in which, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

A second aspect relates to a method for producing a structure having a phase-separated structure, the method including: applying the resin composition for forming a phase-separated structure as described in the first aspect on a support to form a layer containing the block copolymer; and phase-separating the layer containing the block copolymer.

A third aspect relates to a block copolymer containing: a first block; and a second block,
the first block being composed of a polymer having a repeating structure of a constituent unit represented by the following formula (b1),
the second block being composed of a random copolymer having a structure in which a constituent unit represented by the following formula (b2a) and a constituent unit represented by the following formula (b2b) are randomly arranged,
a ratio of a volume of the first block to a total of the volume of the first block and a volume of the second block being 20% by volume or more and 80% by volume or less,

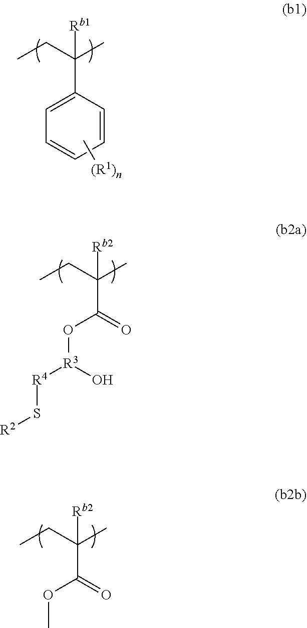

in which, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

According to the present invention, it is possible to provide a resin composition for forming a phase-separated structure capable of forming a phase-separated structure having an excellent vertical orientation, a method for producing a structure having a phase-separated structure using the same, and a block copolymer for use in the resin composition for forming a phase-separated structure.

### BRIEF DESCRIPTION OF THE DRAWINGS

FIG. 1 is a schematic process diagram illustrating an exemplary embodiment of a method for producing a structure having a phase-separated structure; and

FIG. 2 is a diagram illustrating an exemplary embodiment of an optional step.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

As used herein, the term “aliphatic” is defined as a concept relative to aromatic and means, for example, a group or a compound having no aromaticity. Unless otherwise specified, the phrase “alkyl group” means a linear- or branched-chain monovalent saturated hydrocarbon group. The same applies to an alkyl group in an alkoxy group. Unless otherwise specified, the phrase “cycloalkyl group” means a monocyclic cyclic saturated hydrocarbon group. Unless otherwise specified, the phrase “alkylene group” means a linear- or branched-chain divalent saturated hydrocarbon group. The phrase “halogenated alkyl group” means a group in which a portion or all of hydrogen atoms in an alkyl group is substituted with a halogen atom. Examples of the halogen atom include a fluorine atom, a chlorine atom, a bromine atom, or an iodine atom. The phrase “fluorinated alkyl group” or “fluorinated alkylene group” means a group in which a portion or all of hydrogen atoms in an alkyl group or an alkylene group is substituted with a fluorine atom. The phrase “constituent unit” means a monomer unit (monomeric unit) constituting a polymer compound (resin, polymer, or copolymer). The phrase “constituent unit derived from” means a constituent unit derived from cleavage of an ethylenic double bond or a cyclic ether. The phrase “may have a substituent” includes both a case where a hydrogen atom (—H) is substituted with a monovalent group and a case where a methylene group (—CH₂—) is substituted with a divalent group. The term “exposure” means general irradiation with radiation. The term “position α (carbon atom at a position α)” means a carbon atom to which a side chain of a block copolymer is bonded, unless otherwise specified. The “carbon atom at a position α” of a methyl methacrylate unit means a carbon atom to which a carbonyl group in methacrylic acid is bonded. The “carbon atom at a position α” of a styrene unit means a carbon atom to which a benzene ring is bonded. The phrase “number average molecular weight” (Mn) means a number average molecular weight in terms of standard polystyrene as measured by size-exclusion chromatography, unless otherwise specified. The phrase “weight average molecular weight” (Mw) means a weight average molecular weight in terms of standard polystyrene as measured by size-exclusion chromatography, unless otherwise specified. When a value of Mn or Mw is described preceding a unit (gmol⁻¹), the value represents a molar mass. Herein, there may be an asymmetric carbon depending on a structure represented by a chemical formula, and thus an enantiomer or a diastereomer may exist. In that case, these isomers are represented by one representative formula. These isomers may be used alone or used as a mixture.

### <<Resin Composition for Forming Phase-Separated Structure>>

A resin composition for forming a phase-separated structure contains a block copolymer having a first block and a second block. The first block is composed of a polymer having a repeating structure of a constituent unit represented by the following formula (b1). The second block is composed of a random copolymer having a structure in which a constituent unit represented by the following formula (b2a) and a constituent unit represented by the following formula (b2b) are randomly arranged. A ratio of a volume of the first block to a total of the volume of the first block and a volume of the second block is 20% by volume or more and 80% by volume or less.

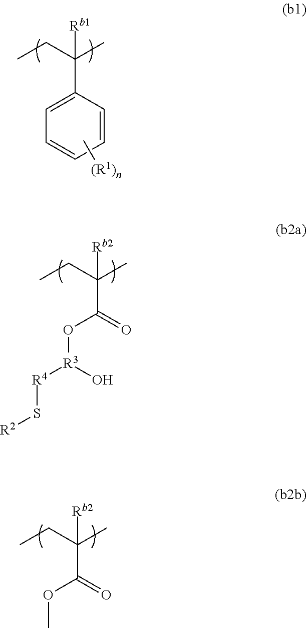

in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

### <Block Copolymer>

The block copolymer is a polymer in which a plurality of types of blocks (sub-constituents of the same type of constituent units repeatedly bonded) are bonded. There may be two, three or more types of blocks constituting the block copolymer. The block copolymer contains the first block and the second block.

### [First Block]

The first block is composed of a polymer having a repeating structure of a constituent unit represented by the following formula (b1) (hereinafter, also referred to as a constituent unit (b1)).

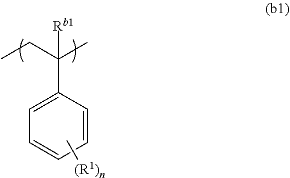

in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group.

The alkyl group which may have an oxygen atom and/or a silicon atom is preferably an alkyl group which may be interrupted with an oxygen atom or may be substituted with an alkylsilyl group. Specific examples thereof include an alkyl group, an alkylsilyl group, an alkylsilylalkyl group, an alkylsilyloxy group, an alkylsilyloxyalkyl group, and an alkoxy group.

Examples of the alkyl group include a methyl group, an ethyl group, an n-propyl group, an isopropyl group, an n-butyl group, a sec-butyl group, and a tert-butyl group.

The alkylsilyl group is preferably a trialkylsilyl group. Specific examples thereof include a trimethylsilyl group. The alkylsilylalkyl group is preferably a trialkylsilylalkyl group. Specific examples thereof include a trimethylsilylmethyl group, a 2-trimethylsilylethyl group, and a 3-trimethylsilyl-n-propyl group. The alkylsilyloxy group is preferably a trialkylsilyloxy group. Specific examples thereof include a trimethylsilyloxy group. The alkylsilyloxyalkyl group is preferably a trialkylsilyloxyalkyl group. Specific examples thereof include a trimethylsilyloxymethyl group, a 2-trimethylsilyloxyethyl group, and a 3-trimethylsilyloxy-n-propyl group. Examples of the alkoxy group include a methoxy group, an ethoxy group, an n-propoxy group, an isopropoxy group, an n-butoxy group, a sec-butoxy group, and a tert-butoxy group.

The total number of carbon atoms in the alkyl group which may be interrupted with an oxygen atom or may be substituted with an alkylsilyl group is preferably 1 or more and 10 or less, more preferably 1 or more and 5 or less, further preferably 1 or more and 3 or less, and particularly preferably 1 or 2.

n is preferably an integer of 0 or more and 3 or less, more preferably 0 or 1, and further preferably 0.

### [Second Block]

The second block is composed of a random copolymer having a structure in which a constituent unit represented by the following formula (b2a) (hereinafter, also referred to as a constituent unit (b2a)) and a constituent unit represented by the following formula (b2b) (hereinafter, also referred to as a constituent unit (b2b)) are randomly arranged.

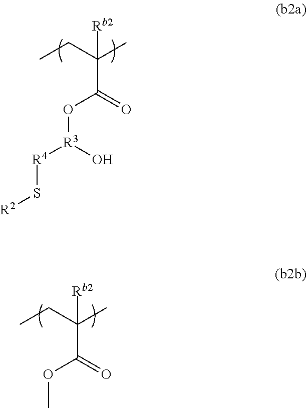

in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.
   (Constituent Unit (b2a))

Examples of R² include an allyl group, an isopropenyl group, an acetyl group, and a thioacetyl group. Among them, an allyl group, an acetyl group, and a thioacetyl group are preferred, and an allyl group and an acetyl group are more preferred.

Specific examples of the chain saturated aliphatic hydrocarbon group having 1 or more and 3 or less carbon atoms as R³ include the following groups. A group bonded to R³ is also shown as a group represented by —O—R³(OH)—R⁴—.
—O—CH(OH)—R⁴—
—O—CH₂CH(OH)—R⁴—
—O—CH(OH)CH₂—R⁴—
—O—CH₂CH₂CH(OH)—R⁴—
—O—CH₂CH(OH)CH₂—R⁴—
—O—CH(OH)CH₂CH₂—R⁴—
—O—CH(CH₃)CH(OH)—R⁴—
—O—C(CH₃)(OH)CH₂—R⁴—
—O—CH(CH₂OH)CH₂—R⁴—
—O—CH₂C(CH₃)(OH)—R⁴—
—O—CH₂CH(CH₂OH)—R⁴—
—O—CH(OH)CH(CH₃)—R⁴—

Among these groups,
—O—CH(OH)—R⁴—,
—O—CH₂CH(OH)—R⁴—,
—O—CH₂CH₂CH(OH)—R⁴—,
—O—CH(CH₃)CH(OH)—R⁴—, and
—O—CH₂C(CH₃)(OH)—R⁴— are preferred, and
—O—CH₂CH(OH)—R⁴— is more preferred.

The alkylene group as R⁴ is preferably a linear- or branched-chain alkylene group, and is more preferably a linear-chain alkylene group. The number of carbon atoms in the alkylene group as R⁴ is preferably 1 or more and 5 or less, more preferably 1 or more and 3 or less, and further preferably 1.

A total of the number of carbon atoms in the chain saturated aliphatic hydrocarbon group as R³ and the number of carbon atoms in the single bond or the alkylene group as R⁴ is preferably 1 or more and 7 or less, more preferably 2 or more and 5 or less, and further preferably 3.

In the formula (b2a), the alkyl group having 1 or more and 5 or less carbon atoms as R^{b2} is preferably a linear- or branched-chain alkyl group having 1 or more and 5 or less carbon atoms. Specific examples thereof include a methyl group, an ethyl group, a propyl group, an isopropyl group, an n-butyl group, a sec-butyl group, a tert-butyl group, an n-pentyl group, a neopentyl group, an isopentyl group, a sec-pentyl group, a 3-pentyl group, and a tert-pentyl group. The halogenated alkyl group having 1 or more and 5 or less carbon atoms is a group in which a portion or all of hydrogen atoms in an alkyl group having 1 or more and 5 or less carbon atoms is substituted with a halogen atom. The halogen atom is particularly preferably a fluorine atom.

In the formula (b2a), R^{b2} is preferably a hydrogen atom, an alkyl group having 1 or more and 5 or less carbon atoms, or a fluorinated alkyl group having 1 or more and 5 or less carbon atoms, and a hydrogen atom or a methyl group is more preferred, and a methyl group is further preferred from the viewpoint of industrial availability.

(Constituent Unit (b2b))

In the formula (b2b), R^{b2} is the same as R^{b2} in the formula (b2a).

In the second block, a ratio of the number of moles of the constituent unit represented by the formula (b2a) to a total of the number of moles of the constituent unit represented by the formula (b2a) and the number of moles of the constituent unit represented by the formula (b2b) is preferably 0.90 or less, more preferably 0.30 or less, and further preferably 0.01 or more and 0.10 or less from the viewpoint of orientation with respect to a guide pattern.

In the block copolymer, the ratio of the volume of the first block to the total of the volume of the first block and the volume of the second block is 20% by volume or more and 80% by volume or less. A ratio of the volume of the first block is preferably 30% by volume or more, and more preferably 35% by volume or more. In addition, the ratio of the volume of the first block is preferably 70% by volume or less, more preferably 65% by volume or less, and further preferably 60% by volume or less.

The ratio of the volume of the first block to the total volume of the first block and the second block in the block copolymer can be determined as follows. From results of ¹H NMR analysis, a mole percentage of each of the first block and the second block in the block copolymer is calculated, and furthermore, a mass percentage of each block is calculated based on a molecular weight of each block. The mass percentage of each block is divided by a density of each block to calculate a volume ratio of each block, and a volume percentage of the first block in the block copolymer is calculated based on the volume ratio. The density of each block can be estimated by an atomic group contribution method (Fedors, R. F. Polym. Eng. Sci. 1974, 14, 147 to 154.). When the first block is a polystyrene block (PS), a density of PS may be 1.05 gm⁻³. When the second block has a constituent unit derived from methyl methacrylate, a density of a structure composed of the constituent unit may be 1.18 gcm⁻³. When the second block has a constituent unit derived from 2-hydroxy-3-(2,2,2-trifluoroethylsulfanyl) propyl methacrylate, a density of a structure composed of the constituent unit may be 1.43 gcm⁻³. Regarding the density of each block, a density described in the literature (Polymer Handbook, 4th ed.; Wiley: New York, 2004.) or the like can also be used.

The block copolymer may have other blocks in addition to the first block and the second block. In a preferred embodiment, the block copolymer is a diblock copolymer composed of a first block and a second block.

A number average molecular weight (Mn) of the block copolymer (in terms of polystyrene by size-exclusion chromatography) is not particularly limited, and is preferably 3,000 or more and 100,000 or less, more preferably 5,000 or more and 50,000 or less, further preferably 6,000 or more and 40,000 or less, and particularly preferably 8,000 or more and 30,000 or less. A molecular-weight dispersion degree (Mw/Mn) of each block constituting the block copolymer is preferably 1.0 or more and 1.5 or less, more preferably 1.0 or more and 1.4 or less, and further preferably 1.0 or more and 1.3 or less.

### [Method for Producing Block Copolymer]

A method for producing the block copolymer is not particularly limited, and for example, the block copolymer can be produced by a production method similar to that described in Japanese Patent No. 7213495.

### <Organic Solvent Component>

The resin composition for forming a phase-separated structure preferably contains an organic solvent. Any organic solvent may be used as an organic solvent component as long as the organic solvent can dissolve each component to be used and form a homogeneous solution. In the related art, any organic solvent selected from known organic solvents as a solvent for a composition including a resin as a main component may be used.

Examples of the organic solvent component include a lactone such as γ-butyrolactone; a ketone such as acetone, methyl ethyl ketone, cyclohexanone, methyl-n-pentyl ketone, methyl isopentyl ketone, or 2-heptanone; a polyhydric alcohol such as ethylene glycol, diethylene glycol, propylene glycol, or dipropylene glycol; a polyhydric alcohol monoacetate such as ethylene glycol monoacetate, diethylene glycol monoacetate, propylene glycol monoacetate, or dipropylene glycol monoacetate; a derivative of the polyhydric alcohol or a derivative of a polyhydric alcohol having an ether bond, such as a monoalkyl ether of the polyhydric alcohol or the polyhydric alcohol monoacetate, such as a monomethyl ether, a monoethyl ether, a monopropyl ether, or a monobutyl ether of the polyhydric alcohol or the polyhydric alcohol monoacetate, or a monophenyl ether of the polyhydric alcohol or the polyhydric alcohol monoacetate [among them, propylene glycol monomethyl ether acetate (PGMEA) or propylene glycol monomethyl ether (PGME) is preferred]; a cyclic ether such as dioxane, or an ester other than a polyhydric alcohol monoacetate and a derivative of the polyhydric alcohols described above, such as methyl lactate, ethyl lactate (EL), methyl acetate, ethyl acetate, butyl acetate, methyl pyruvate, ethyl pyruvate, methyl methoxy propionate, or ethyl ethoxy propionate; and an aromatic organic solvent such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene, or mesitylene. The organic solvent component may be used alone, or two or more thereof may be used as a mixed solvent. Among them, propylene glycol monomethyl ether acetate (PGMEA), propylene glycol monomethyl ether (PGME), cyclohexanone, or ethyl lactate (EL) is preferred.

The organic solvent component in the resin composition for forming a phase-separated structure is not particularly limited. The organic solvent component is determined appropriately according to a coating film thickness such that the resin composition for forming a phase-separated structure has a concentration with which the composition can be applied. The organic solvent component is generally used such that a solid content concentration of the resin composition for forming a phase-separated structure is in a range of 0.2% by mass or more and 70% by mass or less, and preferably 0.2% by mass or more and 50% by mass or less.

### <Optional Component>

The resin composition for forming a phase-separated structure may contain an optional component other than the block copolymer and the organic solvent component described above. Examples of the optional component include another resin, a surfactant, a dissolution inhibiting agent, a plasticizing agent, a stabilizing agent, a coloring agent, an anti-halation agent, a dye, a sensitizing agent, a base proliferating agent, or a basic compound.

### <<Method for Producing Structure Having Phase-Separated Structure>>

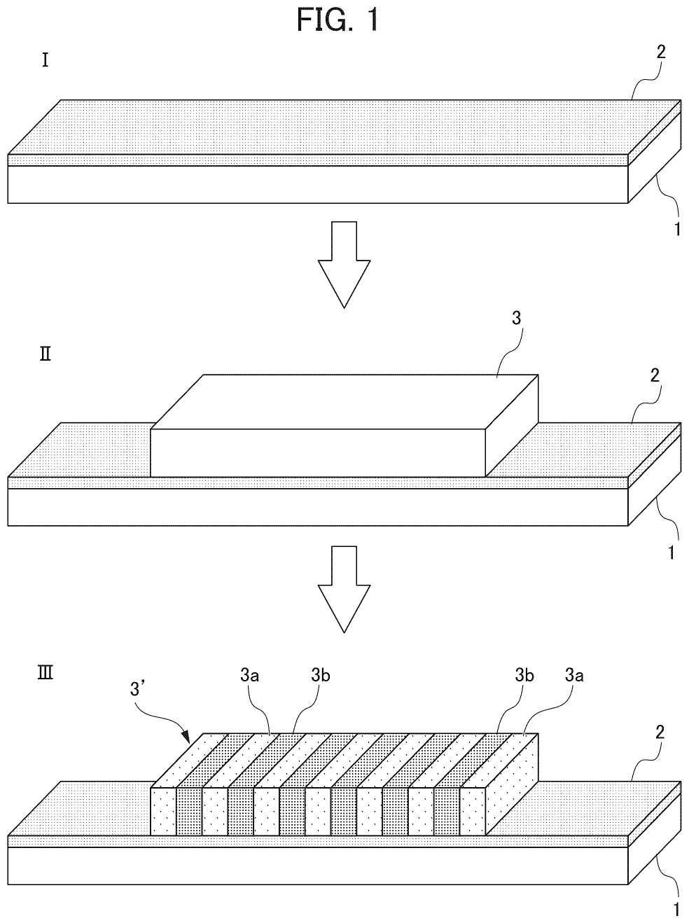

A method for producing a structure having a phase-separated structure includes a step of applying the resin composition for forming a phase-separated structure on a support to form a layer containing a block copolymer (hereinafter, referred to as “Step (i)”), and a step of phase-separating the layer containing the block copolymer (hereinafter, referred to as “Step (ii)”). Hereinafter, such a method for producing a structure having a phase-separated structure will be described in detail with reference to FIG. 1. However, the method for producing a structure having a phase-separated structure according to a second aspect is not limited to the specific aspect shown in FIG. 1.

FIG. 1 shows an exemplary embodiment of the method for producing a structure having a phase-separated structure. In the embodiment shown in FIG. 1, an undercoat agent is first applied on a support 1 to form an undercoat agent layer 2 (FIG. 1 (I)). Next, the resin composition for forming a phase-separated structure is applied on the undercoat agent layer 2 to form a layer (BCP layer) 3 containing a block copolymer (FIG. 1 (II), the above is Step (i)). Then, the resultant is annealed by heating to phase-separate the BCP layer 3 into phases 3a and phases 3b (FIG. 1 (III), Step (ii)). According to such a production method of the embodiment, that is, the production method including Step (i) and Step (ii), a structure 3′ having a phase-separated structure is produced on the support 1 on which the undercoat agent layer 2 is formed.

<Step (i)>

In Step (i), the resin composition for forming a phase-separated structure is applied on the support 1 to form the BCP layer 3. In the embodiment shown in FIG. 1, the undercoat agent is first applied on the support 1 to form the undercoat agent layer 2. By providing the undercoat agent layer 2 on the support 1, a hydrophilic-hydrophobic balance can be achieved between a surface of the support 1 and the layer (BCP layer) 3 containing the block copolymer. That is, when the undercoat agent layer 2 contains a resin component having a constituent unit constituting the first block, adhesion between a phase constituted by the first block in the BCP layer 3 and the support 1 is improved. When the undercoat agent layer 2 contains a resin component having a constituent unit constituting the second block, adhesion between a phase constituted by the second block in the BCP layer 3 and the support 1 is improved. Accordingly, a phase-separated structure oriented in a direction perpendicular to the surface of the support 1 is easily formed by the phase separation of the BCP layer 3.

### Undercoat Agent:

A resin composition can be used as the undercoat agent. The resin composition for the undercoat agent can be appropriately selected from known resin compositions in the related art that is to be used for forming a thin film, depending on a type of a block constituting a block copolymer. The resin composition for the undercoat agent may be, for example, a thermopolymerizable resin composition or may be a photosensitive resin composition such as a positive-type resist composition or a negative-type resist composition. Furthermore, a non-polymerizable film formed by applying a compound serving as a surface treating agent may be used as the undercoat agent layer. For example, a siloxane-based organic monomolecular film formed by applying phenethyltrichlorosilane, octadecyltrichlorosilane, hexamethyldisilazane, or the like as a surface treating agent can also be suitably used as the undercoat agent layer.

Examples of such a resin composition include a resin composition containing a resin having both constituent units constituting the first block and the second block, respectively, and a resin composition containing a resin having both constituent units having high affinity for each block constituting the block copolymer. For example, a composition containing a resin having both styrene and methyl methacrylate as a constituent unit or a compound or a composition including both a moiety having a high affinity with styrene such as an aromatic ring and a moiety having a high affinity with methyl methacrylate (e.g., a highly polar functional group) is preferably used as the resin composition for the undercoat agent. Examples of the resin having both styrene and methyl methacrylate as a constituent unit include a random copolymer of styrene and methyl methacrylate, or an alternating polymer of styrene and methyl methacrylate (polymer in which each monomer is alternately copolymerized). Furthermore, examples of the composition including both a moiety having a high affinity with styrene and a moiety having a high affinity with methyl methacrylate include a composition containing a resin obtained by polymerizing at least a monomer having an aromatic ring and a monomer having a highly polar functional group as monomers. Examples of the monomer having an aromatic ring include a monomer having an aryl group in which one hydrogen atom is removed from an aromatic hydrocarbon ring such as a phenyl group, a biphenyl group, a fluorenyl group, a naphthyl group, an anthryl group, or a phenanthryl group; or a heteroaryl group in which a portion of carbon atoms constituting a ring on any of the above-mentioned groups is substituted with a heteroatom such as an oxygen atom, a sulfur atom, or a nitrogen atom. Furthermore, examples of the monomer having a highly polar functional group include a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Furthermore, examples of the compound including both a moiety having a high affinity with styrene and a moiety having a high affinity with methyl methacrylate include a compound including both an aryl group and a highly polar functional group such as phenethyltrichlorosilane; or a compound including both an alkyl group and a highly polar functional group such as an alkylsilane compound.

The resin composition for the undercoat agent can be produced by dissolving the above-mentioned resin in a solvent. Such a solvent may be any solvent as long as the solvent can dissolve a component to be used and form a homogeneous solution. For example, the same organic solvent component as one exemplified in the above-mentioned description for the resin composition for forming a phase-separated structure may be used.

A type of the support 1 is not particularly limited as long as the resin composition can be applied on the surface of the support 1. Examples thereof include a substrate made of an inorganic material such as a silicon, a metal (e.g., copper, chromium, iron, or aluminum), glass, titanium oxide, silica, or mica; a substrate made of an oxide such as SiO₂; a substrate made of a nitride such as SiN; a substrate made of an oxynitride such as SiON; or a substrate made of an organic material such as acryl resin, polystyrene, cellulose, cellulose acetate, or a phenolic resin. Among them, a silicon substrate (Si substrate) or a metal substrate is suitable, a Si substrate or a copper substrate (Cu substrate) is more suitable, and a Si substrate is particularly suitable. A size or a shape of the support 1 is not particularly limited. The support 1 does not necessarily have a smooth surface, and substrates having various shapes can be appropriately selected. For example, a substrate having a curved surface, a flat plate having an uneven surface, or a flaky substrate may be used.

An inorganic and/or organic film may be provided on the surface of the support 1. Examples of the inorganic film include an inorganic antireflection film (inorganic BARC). Examples of the organic film include an organic antireflection film (organic BARC). The inorganic film can be formed, for example, by applying an inorganic antireflection film composition such as a silicon-based material on a support and baking the resultant. The organic film can be formed, for example, by applying a material for forming an organic film in which a resin component or the like constituting the organic film is dissolved in an organic solvent on a substrate using a spinner or the like, and baking the resultant under heating conditions of preferably 200° C. or higher and 300° C. or lower for preferably 30 seconds or more and 300 seconds or less and more preferably for 60 seconds or more and 180 seconds or less. This material for forming an organic film does not necessarily need sensitivity to light or electron beams like a resist film, and may or may not have the sensitivity. Specifically, a resist or a resin generally used for producing a semiconductor element or a liquid crystal display element may be used. Furthermore, the material for forming an organic film is preferably a material capable of forming an organic film that can be subjected to etching, particularly dry-etching so that an organic film pattern may be formed by etching the organic film using a pattern formed by processing the BCP layer 3 and made of the block copolymer and transferring the pattern to the organic film. Among them, a material capable of forming an organic film that can be subjected to etching such as oxygen plasma etching is preferably used. Such a material for forming an organic film may be a material used for forming an organic film such as organic BARC in the related art. Examples thereof include ARC series manufactured by Nissan Chemical Corporation, AR series manufactured by Rohm and Haas Japan Ltd., or SWK series manufactured by TOKYO OHKA KOGYO CO., LTD.

A method for forming the undercoat agent layer 2 by applying the undercoat agent on the support 1 is not particularly limited and may be any known method the related art. For example, the undercoat agent layer 2 can be formed by applying the undercoat agent on the support 1 using a known method in the related art such as a spin coating or use of a spinner to form a coated film, and drying the coated film. A method for drying the coated film is not limited as long as a solvent contained in the undercoat agent can be volatilized, and, for example, baking may be used. In this case, a baking temperature is preferably 80° C. or higher and 300° C. or lower, more preferably 180° C. or higher and 270° C. or lower, and further preferably 220° C. or higher and 250° C. or lower. A baking time is preferably 30 seconds or more and 600 seconds or less and more preferably 60 seconds or more and 600 seconds or less. A thickness of the undercoat agent layer 2 after drying the coated film is preferably about 10 nm or more and 100 nm or less and more preferably about 40 nm or more and 90 nm or less.

The surface of the support 1 may be previously cleaned before the undercoat agent layer 2 is formed on the support 1. Cleaning of the surface of the support 1 improves coatability of the undercoat agent. A known cleaning treatment method in the related art can be used, and examples thereof include an oxygen plasma treatment, an ozone oxidation treatment, an acid alkali treatment, or a chemical modification treatment.

After the undercoat agent layer 2 is formed, the undercoat agent layer 2 may be rinsed with a rinsing liquid such as a solvent, as necessary. Since an uncrosslinked portion or the like of the undercoat agent layer 2 is removed by rinsing, affinity with at least one block constituting a block copolymer is improved, and thus, a phase-separated structure having a cylindrical structure oriented in a direction perpendicular to the surface of the support 1 is likely to be formed. The rinsing liquid may be any liquid as long as the liquid can dissolve the uncrosslinked portion and, for example, a solvent such as propylene glycol monomethyl ether acetate (PGMEA), propylene glycol monomethyl ether (PGME), or ethyl lactate (EL), or a commercially available thinner liquid may be used. After the cleaning, post-baking may be performed in order to volatilize the rinsing liquid. A temperature condition during the post-baking is preferably 80° C. or higher and 300° C. or lower and more preferably 100° C. or higher and 270° C. or lower. A baking time is preferably 30 seconds or more and 500 seconds or less and more preferably 60 seconds or more and 240 seconds or less. A thickness of the undercoat agent layer 2 after such post-baking is preferably about 1 nm or more and 10 nm or less and more preferably about 2 nm or more and 7 nm or less.

Next, the layer (BCP layer) 3 containing the block copolymer is formed on the undercoat agent layer 2. A method of forming the BCP layer 3 on the undercoat agent layer 2 is not particularly limited, and, for example, may be a method including applying the resin composition for forming a phase-separated structure according to the above-mentioned embodiment on the undercoat agent layer 2 by a known method in the related art such as spin coating or use of a spinner to form a coated film and drying the coated film.

A thickness of the BCP layer 3 need only be sufficient for phase separation to occur. Considering a type of the support 1, or a size of a structural period or uniformity of a nanostructure of the phase-separated structure to be formed, or the like, the thickness is preferably 20 nm or more and 100 nm or less and more preferably 30 nm or more and 80 nm or less. For example, when the support 1 is a Si substrate, a thickness of the BCP layer 3 is preferably adjusted to 10 nm or more and 100 nm or less and more preferably 30 nm or more and 80 nm or less.

<Step (ii)>

In Step (ii), the BCP layer 3 formed on the support 1 is phase-separated. After Step (i), the support 1 is annealed by heating to form a phase-separated structure in which at least a part of the surface of the support 1 is exposed by selective removal of the block copolymer. That is, the structure 3′ having the phase-separated structure in which the phase 3a and the phase 3b are phase-separated is produced on the support 1. A temperature condition during the annealing treatment is preferably a glass transition temperature of a block copolymer used or higher and lower than its thermal decomposition temperature. For example, when the block copolymer is a polystyrene-polymethyl methacrylate (PS-PMMA) block copolymer (mass average molecular weight: 5000 or more and 100000 or less), the temperature condition is preferably 180° C. or higher and 270° C. or lower. A heating time is preferably 30 seconds or more and 3600 seconds or less. The annealing treatment is preferably performed in a less reactive gas such as nitrogen.

### <Optional Step>

The method for producing a structure having a phase-separated structure is not limited to the above-mentioned embodiment and may include a step other than Step (i) and Step (ii) (optional step).

Such an optional step includes a step of selectively removing a phase constituted by at least one of the first block and the second block constituting the block copolymer from the BCP layer 3 (hereinafter, referred to as “Step (iii)”), a guide pattern formation step, or the like.

Regarding Step (iii)

In Step (iii), a phase constituted by at least one of the first block and the second block constituting the block copolymer is selectively removed from the BCP layer formed on the undercoat agent layer 2. This results in formation of a fine pattern (polymer nanostructure).

Examples of the method for selectively removing the phase constituted by the block include a method for subjecting the BCP layer to an oxygen plasma treatment or a method for subjecting the BCP layer to a hydrogen plasma treatment. For example, when the BCP layer containing the block copolymer is phase-separated and then the BCP layer is subjected to an oxygen plasma treatment, a hydrogen plasma treatment, or the like, a phase constituted by a first block (b1) is not selectively removed, but a phase constituted by a second block (b2) is selectively removed.

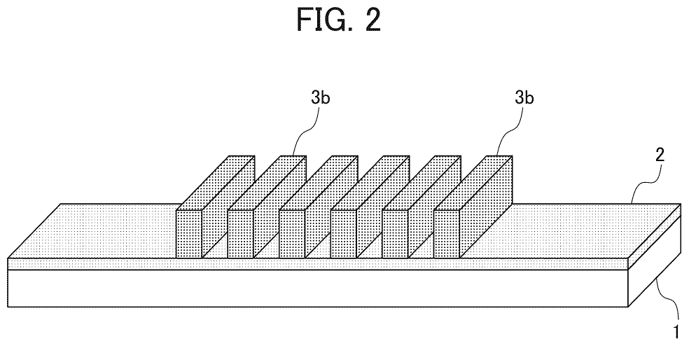

FIG. 2 shows an exemplary embodiment of Step (iii). In the embodiment shown in FIG. 2, the structure 3′ produced on the support 1 in Step (ii) is subjected to an oxygen plasma treatment to selectively remove the phases 3a, resulting in formation of a pattern (polymer nanostructure) constituted by the phases 3b apart from each other. In this case, the phase 3b is the phase constituted by the first block, and the phase 3a is the phase constituted by the second block.

The support 1 with a pattern formed by phase separation of the BCP layer 3 made of the block copolymer as described above can be used as is, or a shape of the pattern (polymer nanostructure) on the support 1 can be changed by further heating. A temperature condition during the heating is preferably a glass transition temperature of the block copolymer used or higher and lower than its thermal decomposition temperature. The heating is preferably performed in a less reactive gas such as nitrogen.

### Regarding Guide Pattern Formation Step

The method for producing a structure having a phase-separated structure may include a step of providing a guide pattern on the undercoat agent layer (guide pattern formation step) between Step (i) and Step (ii) described above. This allows an array structure of the phase-separated structure to be controlled. For example, even a block copolymer from which a fingerprint-shaped phase-separated structure is randomly formed when a guide pattern is not provided, a groove structure of a resist film can be provided on a surface of the undercoat agent layer to obtain a phase-separated structure oriented along the groove. According to this principle, a guide pattern may be provided on the undercoat agent layer 2. Further, in the case where a surface of the guide pattern has an affinity with any of blocks constituting the above-mentioned block copolymer, a phase-separated structure having a cylindrical structure oriented in a direction perpendicular to the surface of the support is likely to be formed.

The guide pattern can be formed using, for example, a resist composition. For the resist composition for forming the guide pattern, a resist composition having an affinity with any of blocks constituting the above block copolymer can be appropriately selected from resist compositions to be generally used for forming a resist pattern or a modified product thereof. The resist composition may be either a positive-type resist composition from which a positive-type pattern is formed, that is, an exposed area of a resist film is dissolved and removed or a negative-type resist composition from which a negative-type pattern is formed, that is, an unexposed area of a resist film is dissolved and removed, but a negative-type resist composition is preferred. The negative-type resist composition is preferably a resist composition that contains, for example, an acid generating agent and a base material component having a solubility in an organic solvent-containing developing solution that decreases under action of an acid, the base material component containing a resin component that has a constituent unit degraded under action of an acid to have an increased polarity. After a BCP composition is poured onto the undercoat agent layer on which the guide pattern is formed, an annealing treatment is performed to cause phase separation. Therefore, a composition capable of forming a resist film having excellent solvent resistance and heat resistance is preferably used as the resist composition for forming the guide pattern.

### <<Block Copolymer>>

The block copolymer contains the first block and the second block. The first block is composed of a polymer having a repeating structure of a constituent unit represented by the following formula (b1). The second block is composed of a random copolymer having a structure in which a constituent unit represented by the following formula (b2a) and a constituent unit represented by the following formula (b2b) are randomly arranged. A ratio of a volume of the first block to a total of the volume of the first block and a volume of the second block is 20% by volume or more and 80% by volume or less.

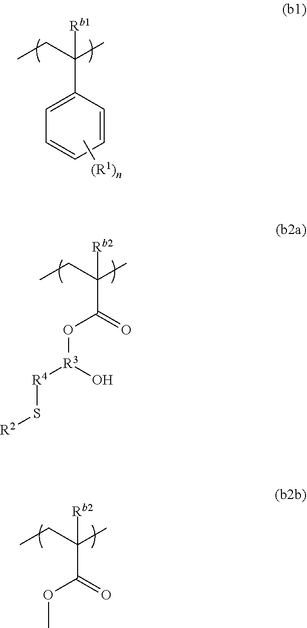

in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

A preferred embodiment of the block copolymer is the same as that of the block copolymer contained in the resin composition for forming a phase-separated structure.

As described above, the present inventors provide the following aspects (1) to (8).
(1) A resin composition for forming a phase-separated structure, the resin composition containing: a block copolymer having a first block and a second block,
   the first block being composed of a polymer having a repeating structure of a constituent unit represented by the following formula (b1),
   the second block being composed of a random copolymer having a structure in which a constituent unit represented by the following formula (b2a) and a constituent unit represented by the following formula (b2b) are randomly arranged,
   a ratio of a volume of the first block to a total of the volume of the first block and a volume of the second block being 20% by volume or more and 80% by volume or less,

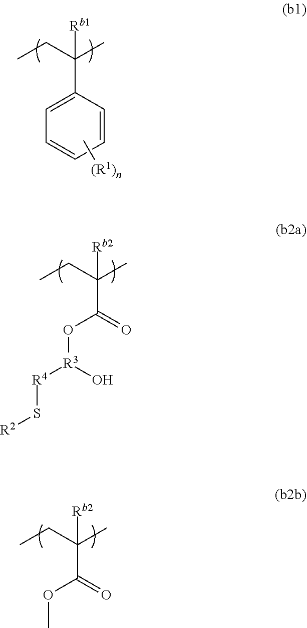

in which, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.
(2) The resin composition for forming a phase-separated structure as described in aspect (1), in which in the second block, a ratio of the number of moles of the constituent unit represented by the formula (b2a) to a total of the number of moles of the constituent unit represented by the formula (b2a) and the number of moles of the constituent unit represented by the formula (b2b) is 0.90 or less.
(3) The resin composition for forming a phase-separated structure as described in aspect (2), in which the ratio is 0.30 or less.
(4) The resin composition for forming a phase-separated structure as described in aspect (3), in which the ratio is 0.01 or more and 0.10 or less.
(5) The resin composition for forming a phase-separated structure as described in any one of aspects (1) to (4), in which R² is an allyl group, an acetyl group, or a thioacetyl group.
(6) A method for producing a structure having a phase-separated structure, the method including: applying the resin composition for forming a phase-separated structure as described in any one of aspects (1) to (5) on a support to form a layer containing the block copolymer; and phase-separating the layer containing the block copolymer.
(7) A block copolymer containing: a first block; and a second block,
   the first block being composed of a polymer having a repeating structure of a constituent unit represented by the following formula (b1),
   the second block being composed of a random copolymer having a structure in which a constituent unit represented by the following formula (b2a) and a constituent unit represented by the following formula (b2b) are randomly arranged,
   a ratio of a volume of the first block to a total of the volume of the first block and a volume of the second block being 20% by volume or more and 80% by volume or less,

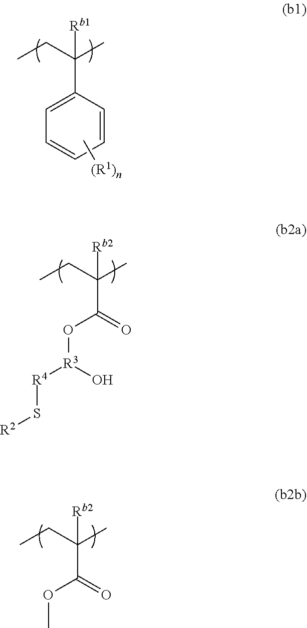

in which, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

### Examples

Although the present invention will be described in more detail with reference to Examples, the present invention is not limited to Examples.

### <Synthesis of BCP Precursor>

### [Synthesis of BCP Precursor (1)]

All anionic polymerization was performed under an argon atmosphere. 200 mL of tetrahydrofuran (THF) and lithium chloride (LiCl) (353 mg, 8.34 mmol) were transferred to a 300 mL Schlenk flask and cooled to −78° C. in a Coolnics bath. Sec-butyllithium (Sec-BuLi) (1.05 M hexane/cyclohexane solution) was added to the Schlenk flask until a color of the solution changed to yellow. The Schlenk flask was removed from the Coolnics bath and warmed at room temperature until the solution became colorless. The Schlenk flask was again cooled to −78° C. in the Coolnics bath and sec-BuLi (1.12 mL, 1.04 mmol) was added as an initiator. Styrene (20.0 mL, 0.174 mol) was added and stirred for 30 minutes. As a result, a bright orange solution was obtained. 1,1-diphenylethylene (DPE) (1.07 mL, 4.71 mmol) was added, and the color of the solution changed to deep red. After stirring for 30 minutes, a monomer mixture of methyl methacrylate (MMA) (13.9 g, 0.139 mol) and glycidyl methacrylate (GMA) (4.98 g, 0.035 mol) was added and stirred for 30 minutes. The color of the solution changed from red to transparent. The polymerization was terminated by adding 3 mL of degassed methanol (MeOH) to the Schlenk flask as a terminator. The Schlenk flask was removed from the Coolnics bath, and the solution was poured into MeOH for reprecipitation. A precipitated solid was filtered and then dried under reduced pressure at 40° C. to obtain a white powder of a BCP precursor (1) (34.2 g, 88% yield). Mn and a dispersion degree (PDI=Mw/Mn) of the BCP precursor (1) measured by size-exclusion chromatography (SEC) were 24,900 and 1.07, respectively.

¹H NMR (400 MHz, CDCl₃, δ, ppm): 0.85 (s, α-CH₃, PMMA), 1.01 (s, α-CH₃, PGMA), 1.23 to 1.69 (br, backbone, —CH₂—CH—, PS), 1.74 to 2.02 (br, backbone, —CH₂—CH—, PS, br, backbone, —CH₂—C(CH₃)—, PGMA and PMMA), 2.63 (s, —CH₂—CH(CH₂)—O—, PGMA), 2.84 (s, —CH₂CH(CH₂)—O—, PGMA), 3.21 (s, —CH₂—CH(CH₂)—O—, PGMA), 3.59 (s, —OCH₃, PMMA), 3.79 (s, —(C═O)O—CH₂—, PGMA), 4.28 (d, —(C═O)O—CH₂—, PGMA), 6.39 to 6.85 (m, o-aromatic, PS), and 6.91 to 7.42 (m, m-, p-aromatic, PS).

### [Synthesis of BCP Precursor (2)]

A BCP precursor (2) was synthesized in the same manner as in the synthesis of the above BCP precursor (1), except that an amount of styrene used was 26.6 mL (0.232 mol), an amount of MMA used was 11.3 g (0.112 mol), and an amount of GMA used was 0.75 g (5.30 mmol). Mn and a dispersion degree (PDI=Mw/Mn) of the BCP precursor (2) measured by size-exclusion chromatography (SEC) were 26,200 and 1.06, respectively.

### [Synthesis of BCP Precursor (3)]

A BCP precursor (3) was synthesized in the same manner as in the synthesis of the above BCP precursor (1), except that an amount of styrene used was 26.6 mL (0.232 mol), an amount of MMA used was 10.5 g (0.105 mol), and an amount of GMA used was 1.75 g (12.3 mmol). Mn and a dispersion degree (PDI=Mw/Mn) of the BCP precursor (3) measured by size-exclusion chromatography (SEC) were 25,900 and 1.06, respectively.

### [Synthesis of BCP Precursor (4)]

A BCP precursor (4) was synthesized in the same manner as in the synthesis of the above BCP precursor (1), except that an amount of styrene used was 26.6 mL (0.232 mol), an amount of MMA used was 10.2 g (0.102 mol), and an amount of GMA used was 2.33 g (16.4 mmol). Mn and a dispersion degree (PDI=Mw/Mn) of the BCP precursor (4) measured by size-exclusion chromatography (SEC) were 25,800 and 1.06, respectively.

### <Synthesis of Block Copolymer>

### [Synthesis of BCP (A1)]

10 g of the BCP precursor (1) and THF (10 wt % solution) were placed in a 200 mL glass tube and immersed in an ice-water bath. 1 wt % lithium hydroxide (LiOH) aqueous solution (0.05 mol equivalents of LiOH/GMA unit) and 2,2,2-trifluoroethanethiol (2 mol equivalents/GMA unit) were added to the glass tube. After stirring for 20 minutes at room temperature, a reactor was set to 40° C. and stirred for 3 hours to synthesize BCP (A1). According to Mn and a PHEMA fraction of the synthesized BCP (A1), residual reagents were removed by repeated precipitation with methanol or methanol/hexane several times. The product was dried overnight at room temperature under reduced pressure to obtain a white powder of the BCP (A1). Mn and a dispersion degree (PDI=Mw/Mn) of the BCP (A1) measured by size-exclusion chromatography (SEC) were 26,500 and 1.06, respectively.

¹H NMR (400 MHz, Acetone-d₆, δ, ppm): 0.84 (s, α-CH₃, PMMA), 0.87 (s, α-CH₃, PMMA), 1.00 (s, α-CH₃, PMMA), 1.03 (s, α-CH₃, PGMA), 1.23 to 1.73 (br, backbone, —CH₂—CH—, PS), 1.75 to 2.23 (br, backbone, —CH₂—CH—, PS, br, backbone, —CH₂—C(CH₃)—, PGMA and PMMA), 2.78 to 3.00 (d, CH(OH)—CH₂—S—, PHFMA), 3.40 to 3.77 (s, —S—CH₂—CF₃, PHFMA), 3.54 to 3.75 (s, —OCH₃, PMMA), 3.92 to 4.07 (d, —(C═O)O—CH₂—, PHFMA), 4.07 to 4.18 (m, —CH(OH)—, PHFMA), 4.50 to 4.72 (br, —CH(OH)—, PHFMA), 6.36 to 6.84 (m, o-aromatic, PS), and 6.85 to 7.35 (m, m-, p-aromatic, PS).

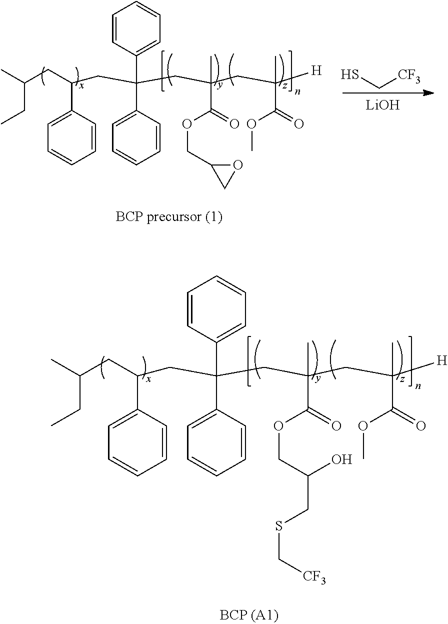

### [Synthesis of BCP (B1)]

BCP (B1) was synthesized in the same manner as in the synthesis of the BCP (A1), except that thioacetic acid was used instead of 2,2,2-trifluoroethanethiol. Mn and a dispersion degree (PDI=Mw/Mn) of the BCP (B1) measured by size-exclusion chromatography (SEC) were 26,500 and 1.06, respectively.

### [Synthesis of BCP (B2) to BCP (B4)]

BCP (B2) to BCP (B4) were synthesized in the same manner as in the synthesis of the BCP (B1), except that the BCP precursors (2) to (4) were used respectively instead of the BCP precursor (1). Mn and a dispersion degree (PDI=Mw/Mn) of the BCP (B2) measured by size-exclusion chromatography (SEC) were 26,500 and 1.06, respectively. Mn and a dispersion degree (PDI=Mw/Mn) of the BCP (B3) measured by size-exclusion chromatography (SEC) were 26,500 and 1.06, respectively. Mn and a dispersion degree (PDI=Mw/Mn) of the BCP (B4) measured by size-exclusion chromatography (SEC) were 26,500 and 1.06, respectively.

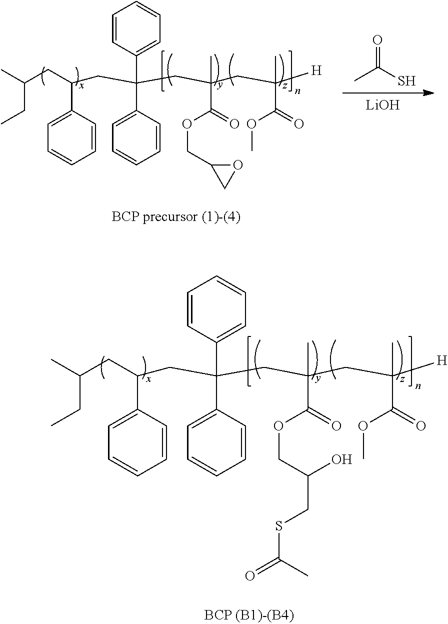

### [Synthesis of BCP (C1)]

BCP (C1) was synthesized in the same manner as in the synthesis of the BCP (A1), except that 2-propene-1-thiol was used instead of 2,2,2-trifluoroethanethiol. Mn and a dispersion degree (PDI=Mw/Mn) of the BCP (C1) measured by size-exclusion chromatography (SEC) were 26,500 and 1.06, respectively.

### [Synthesis of BCP (C2) and BCP (C3)]

BCP (C2) and BCP (C3) were synthesized in the same manner as in the synthesis of the BCP (C1), except that the BCP precursor (2) and the BCP precursor (3) were used respectively instead of the BCP precursor (1). Mn and a dispersion degree (PDI=Mw/Mn) of the BCP (C2) measured by size-exclusion chromatography (SEC) were 26,500 and 1.06, respectively. Mn and a dispersion degree (PDI=Mw/Mn) of the BCP (C3) measured by size-exclusion chromatography (SEC) were 26,500 and 1.06, respectively.

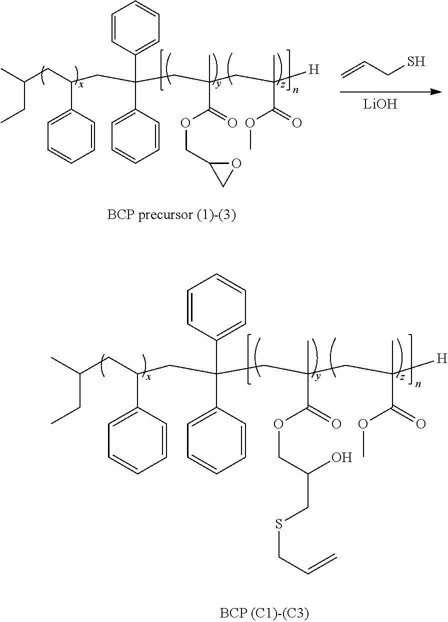

### <Measurement of Volume of Each Block>

A mole percentage of each block in the block copolymer was calculated from results of ¹H NMR analysis, and a mass percentage of each block was also calculated. Next, a volume ratio of each block was calculated by dividing the mass percentage of each block by a density of each block. The volume ratio was used to calculate a ratio of a volume of a polystyrene block in a total volume of the block copolymer. The density of each block was estimated by an atomic group contribution method (Fedors, R. F. Polym. Eng. Sci. 1974, 14, 147 to 154.). A density of the polystyrene block was 1.05 gm⁻³. A density of a structure composed of a constituent unit derived from methyl methacrylate was 1.18 gcm⁻³. A density of a structure composed of a constituent unit derived from 2-hydroxy-3-(2,2,2-trifluoroethylsulfanyl) propyl methacrylate was 1.43 gcm⁻³ (BCP (A1)). In the BCP (B1) to the BCP (B4) and the BCP (C1) to the BCP (C3), a density of a structure composed of a constituent unit corresponding to the constituent unit (b2a) was 1.18 gcm⁻³.

Table 1 summarizes the number average molecular weight (Mn) of each block copolymer synthesized above, and the volume ratio (% by volume) of the polystyrene block (PS) to the total volume of the block copolymer. In addition, Table 2 summarizes, for each block copolymer synthesized above, a ratio (x:y:z) of the number of moles of the constituent unit (b1), the number of moles of the constituent unit (b2a), and the number of moles of the constituent unit (b2b) to the total number of moles of the constituent units, and a ratio (y/(y+z)) of the number of moles of the constituent unit (b2a) to the total of the number of moles of the constituent unit (b2a) and the number of moles of the constituent unit (b2b).

TABLE 1

| | | % BY VOLUME |
|---|---|---|
| | Mn | OF PS |
| BCP (A1) | 26,500 | 51 |
| BCP (B1) | 26,500 | 51 |
| BCP (B2) | 26,500 | 69 |
| BCP (B3) | 26,500 | 69 |
| BCP (B4) | 26,500 | 69 |
| BCP (C1) | 26,500 | 51 |
| BCP (C2) | 26,500 | 69 |
| BCP (C3) | 26,500 | 69 |

### <Preparation of Resin Composition for Forming Phase-Separated Structure, and Production of Structure Having Phase-Separated Structure>

Each BCP shown in Table 2 and propylene glycol monomethyl ether acetate were mixed and dissolved to prepare a resin composition for forming a phase-separated structure (solid content concentration: 0.8% by mass) in each example.

After a guide pattern was formed with a resist composition, a structure having a phase-separated structure was obtained by a production method including Step (i) and Step (ii) shown below using the resin composition for forming a phase-separated structure in each example.

### Formation of Guide Pattern

An organic antireflection film composition “ARC-29A” (trade name, manufactured by Brewer Science) was applied to a 12-inch silicon wafer using a spinner, and baked on a hotplate at 205° C. for 60 seconds to dry, thereby forming an organic antireflection film having a film thickness of 89 nm. The organic antireflection film was spin-coated with a neutral film composition solution (undercoat agent), and then heated at 250° C. for 600 seconds. As a result, a thin film made of the neutral film composition having a film thickness of 60 nm was formed on a surface of the substrate. Then, the undercoat agent layer was rinsed with an OK73 thinner (trade name, manufactured by TOKYO OHKA KOGYO CO., LTD.) for 15 seconds to remove a random copolymer such as an uncrosslinked portion. Thereafter, baking was performed at 100° C. for 60 seconds. A resist film for forming a guide pattern was applied on the film using a spinner, pre-baked (PAB) on a hotplate, and dried to form a resist film for forming a guide pattern having a film thickness of 90 nm. An ArF excimer laser (193 nm) was selectively irradiated through a mask pattern using an ArF exposure device XT-1900Gi (manufactured by ASML). Then, post-exposure baking (PEB) was performed, followed by development with butyl acetate and shake-off drying. Then, post-baking was performed at 100° C. for 1 minute, and then at 200° C. for 5 minutes to form a guide pattern having a space dimension four times a d value of a block copolymer to be used.

As the neutral film composition solution, the following NL-1 or NL-2 was used.
NL-1: PGMEA solution (copolymer concentration: 2.0% by mass) of a copolymer having a styrene (St) unit, a methyl methacrylate (MMA) unit, and a 2-hydroxyethyl methacrylate (HEMA) unit (St/MMA/HEMA=49/46/5 (mol %), number average molecular weight: 28,000).
NL-2: PGMEA solution (copolymer concentration: 2.0% by mass) of a copolymer having a styrene (St) unit, a methyl methacrylate (MMA) unit, and a 2-hydroxyethyl methacrylate (HEMA) unit (St/MMA/HEMA=70/25/5 (mol %), number average molecular weight: 29,000)

### Step (i):

The resin composition in each example was spin-coated on the undercoat agent layer to a film thickness of 30 nm to form a resin composition layer (layer containing a block copolymer).

### Step (ii):

The resin composition layer formed on the undercoat agent layer was pre-baked at 90° C. for 60 seconds in a nitrogen atmosphere, and then annealed at 220° C. for 30 minutes in a nitrogen atmosphere to form a phase-separated structure.

Step (iii)

A substrate on which the phase-separated structure was formed was subjected to an oxygen plasma treatment (200 mL/min, 40 Pa, 40° C., 200 W, 10 seconds) using TCA-3822 (manufactured by TOKYO OHKA KOGYO CO., LTD.) to selectively remove a phase constituted by PMMA.

### (Evaluation of Vertical Orientation)

A surface (phase separation state) of the obtained substrate was observed with a length measuring SEM (scanning electron microscope, trade name: CG6300, manufactured by Hitachi High-Technologies Corporation). As a result of such observation, phase separation performance was evaluated based on the following evaluation criteria. The results are shown in Table 2 as “Phase vertical orientation”.
A: Vertical orientation was observed over the entire surface.
B: Vertical orientation was not observed partially.

### (Evaluation of Guide Array)

A surface (phase separation state) of the obtained substrate was observed with a length measuring SEM (scanning electron microscope, trade name: CG6300, manufactured by Hitachi High-Technologies Corporation). As a result of such observation, a guide array was evaluated based on the following evaluation criteria. The results are shown in Table 2 as “Guide array”.
A: Phase separation structure is formed over the entire surface of a substrate on which a guide pattern is formed.
B: Phase separation structure is not formed in a portion of a substrate on which a guide pattern is formed.

TABLE 2

| | | | | Undercoat | Vertical | |
|---|---|---|---|---|---|---|
| | BCP | x:y:z | y/(y + z) | agent | orientation | Guide array |
| Comparative | BCP | 50:10:40 | 0.2 | NL-1 | B | B |
| Example 1 | (A1) | | | | | |
| Example 1 | BCP | 50:10:40 | 0.2 | NL-1 | A | B |
| | (B1) | | | | | |
| Example 2 | BCP | 50:10:40 | 0.2 | NL-1 | A | B |
| | (C1) | | | | | |
| Example 3 | BCP | 68:1:31 | 0.03 | NL-2 | A | A |
| | (B2) | | | | | |
| Example 4 | BCP | 68:1:31 | 0.03 | NL-2 | A | A |
| | (C2) | | | | | |
| Example 5 | BCP | 68:3:29 | 0.09 | NL-2 | A | A |
| | (B3) | | | | | |
| Example 6 | BCP | 68:3:29 | 0.09 | NL-2 | A | A |
| | (C3) | | | | | |
| Example 7 | BCP | 68:4:28 | 0.13 | NL-2 | A | B |
| | (B4) | | | | | |

As shown in Tables 1 and 2, it was confirmed that in Examples 1 to 7 containing a predetermined block copolymer, a phase-separated structure having a good vertical orientation was formed. In particular, it was confirmed that in Examples 3 to 6 in which a ratio of the number of moles of the constituent unit (b2a) was 0.10 or less, good array property with respect to the guide pattern was also achieved in addition to a vertical orientation.

What is claimed is:

1. A resin composition for forming a phase-separated structure, the resin composition comprising a block copolymer having a first block and a second block,
wherein the first block comprises a polymer having a repeating structure of a constituent unit represented by the following formula (b1),
the second block being comprises a random copolymer having a structure in which a constituent unit represented by the following formula (b2a) and a constituent unit represented by the following formula (b2b) are randomly arranged, and
a ratio of a volume of the first block to a total of the volume of the first block and a volume of the second block is 20% by volume or more and 80% by volume or less, 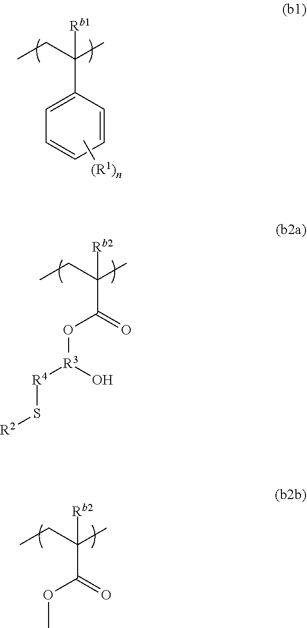
wherein, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.

2. The resin composition for forming a phase-separated structure according to claim 1, wherein in the second block, a ratio of the number of moles of the constituent unit represented by the formula (b2a) to a total of the number of moles of the constituent unit represented by the formula (b2a) and the number of moles of the constituent unit represented by the formula (b2b) is 0.90 or less.

3. The resin composition for forming a phase-separated structure according to claim 2, wherein the ratio is 0.30 or less.

4. The resin composition for forming a phase-separated structure according to claim 3, wherein the ratio is 0.01 or more and 0.10 or less.

5. The resin composition for forming a phase-separated structure according to claim 1, wherein R² is an allyl group, an acetyl group, or a thioacetyl group.

6. A method for producing a structure comprising a phase-separated structure, the method comprising:
applying the resin composition for forming a phase-separated structure according to claim 1 on a support to form a layer comprising the block copolymer; and
phase-separating the layer comprising the block copolymer.

7. A block copolymer comprising a first block and a second block,
the first block comprising a polymer having a repeating structure of a constituent unit represented by the following formula (b1),
the second block comprising a random copolymer having a structure in which a constituent unit represented by the following formula (b2a) and a constituent unit represented by the following formula (b2b) are randomly arranged, and
a ratio of a volume of the first block to a total of the volume of the first block and a volume of the second block is 20% by volume or more and 80% by volume or less, 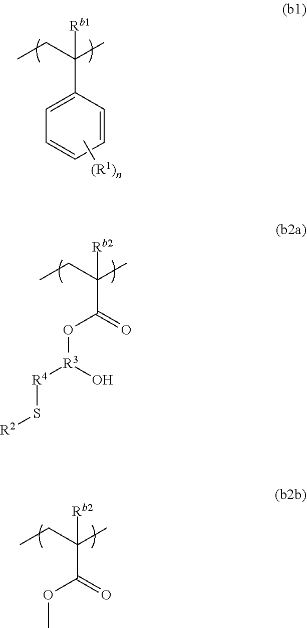
wherein, in the formula (b1), R¹ is an alkyl group which may have an oxygen atom and/or a silicon atom, n is an integer of 0 or more and 5 or less, and when n is an integer of 2 or more, a plurality of R¹ may be same as or different from each other, and R^{b1} is a hydrogen atom or a methyl group,
in the formula (b2a), R² is a group composed of three atoms selected from the group consisting of a carbon atom, an oxygen atom, and a sulfur atom, and a hydrogen atom, and having one double bond, and the three atoms may be same as or different from each other,
R³ is a chain saturated aliphatic hydrocarbon group having 1 or more and 3 or less carbon atoms, and
R⁴ is a single bond or an alkylene group,
a total of the number of carbon atoms in the chain saturated aliphatic hydrocarbon group as the R³ and the number of carbon atoms in the single bond or the alkylene group as the R⁴ is 1 or more and 10 or less, and
in the formula (b2a) and the formula (b2b), R^{b2} are each independently a hydrogen atom, an alkyl group having 1 or more and 5 or less carbon atoms, or a halogenated alkyl group having 1 or more and 5 or less carbon atoms, and a plurality of R^{b2} may be same as or different from each other.
